(19) United States
(12) Patent Application Publication
(10) Pub. No.: US 2008/0197357 A1
(43) Pub. Date: Aug. 21, 2008

(54) DISPLAY PANEL AND MANUFACTURING METHOD

(76) Inventors: Gyung-Soon PARK, Yongin-si (KR); Chun-Gi YOU, Hwaseong-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/966,856

(22) Filed: Dec. 28, 2007

(30) Foreign Application Priority Data
Feb. 16, 2007 (KR) 10-2007-0016407

(51) Int. Cl. H01L 29/04; H01L 21/336

(52) U.S. Cl. 257/72; 438/151; 257/E29.003; 257/E21.413

(57) ABSTRACT

A display panel includes a semiconductor layer formed on a substrate, a first insulating layer formed on the semiconductor layer, a gate line including a gate electrode and formed on the first insulating layer, a second insulating layer formed on the gate line, and a data line including a source electrode and a drain electrode formed on the second insulating layer. The second insulating layer covered with the drain electrode and the data line may be thicker than the second insulating layer not covered with the drain electrode and the data line. The data conductors are disposed on a higher interlayer insulating layer than the others such that diffused or migrating aluminum material is placed on the lower interlayer insulating layer to be prevented from being connected to the data conductors.

### CROSS-REFERENCE TO RELATED APPLICATION

This application claims priority to and the benefit of Korean Patent Application No. 10-2007-0016407 filed in the Korean Intellectual Property Office on Feb. 16, 2007, the entire contents of which are incorporated herein by reference.

### BACKGROUND OF THE INVENTION

1. Field of the Invention

The present invention relates to a display panel and, more particularly, to a polysilicon thin film transistor array panel and a manufacturing method therefor.

2. Description of the Related Art

A thin film transistor (TFT) is generally used as a switching element to individually drive each pixel in a flat panel display such as a liquid crystal display or an organic light emitting display. A thin film transistor array panel including a plurality of TFTs has a plurality of pixel electrodes respectively connected to the TFTs, a plurality of gate lines for transmitting gate signals (scanning signals) to the TFTs, and a plurality of data lines for transmitting data signals to the TFTs.

The TFT includes a gate electrode connected to the gate line, a source electrode connected to the data line, a drain electrode connected to the pixel electrode, and a semiconductor layer overlapping the gate electrode via an insulating layer. The TFT controls the data signals applied to the pixel electrode according to the scanning signal of the gate line. The semiconductor layer of the TFT includes polycrystalline silicon or amorphous silicon.

Because a polysilicon TFT has relatively higher electron mobility than amorphous silicon TFT, the polysilicon TFT made be applied to a high quality driving circuit. Also, the polysilicon TFT enables implementation of a chip-on-glass technique in which a display panel embeds its driving circuits therein.

As the lengths of the signal lines increase along with the LCD size, increased line resistance, signal delay and voltage drop occur, dictating that wiring be made of a material having low resistivity, such as aluminum (Al). When aluminum (Al) is used in wiring, signal lines may have a multi-layered structure including Al layer and another layer. However, Al included in the data line, the source electrode, and the drain electrode may diffuse and migrate resulting in a short between the data line, the source electrode, and the drain electrode.

### SUMMARY OF THE INVENTION

A display panel according to an embodiment of the present invention includes a semiconductor layer formed on a substrate, a first insulating layer formed on the semiconductor layer, a gate line including a gate electrode and formed on the first insulating layer, a second insulating layer formed on the gate line, and a data line including a source electrode and a drain electrode formed on the second insulating layer. The second insulating layer covered with the drain electrode and the data line may be thicker than the second insulating layer not covered with the drain electrode and the data line.

The thickness of the second insulating layer not covered with the drain electrode and the data line may be about 50% to 70% of that of the second insulating layer covered with the drain electrode and the data line.

The second insulating layer may have a dual-layered structure including a lower insulating layer and an upper insulating layer, the lower insulating layer may have a constant thickness, and the upper insulating layer may have a position-dependent thickness.

The drain electrode and the data line may include aluminum.

The drain electrode and the data line may have a triple-layered structure including a lower layer including molybdenum, a middle layer including aluminum, and an upper layer including molybdenum.

The first insulating layer and the second insulating layer may have first and second contact holes exposing the semiconductor layer, and the source electrode and the drain electrode may be connected to the semiconductor layer through the first contact hole and the second contact hole, respectively.

The display panel may further include a passivation layer formed on the data line and a pixel electrode formed on the passivation layer.

A manufacturing method of a display panel according to an embodiment of the present invention includes forming a semiconductor layer on a substrate, forming a first insulating layer on the semiconductor layer, forming a gate electrode on the first insulating layer, forming a second insulating layer on the gate electrode, forming a source electrode and a drain electrode on the second insulating layer, and etching the second insulating layer using the source electrode and the drain electrode as an etch mask to become thin.

The thickness of the second insulating layer not covered with the source electrode and the drain electrode may be about 50% to 70% of that of the second insulating layer covered with the source electrode and the drain electrode.

The second insulating layer may have a dual-layered structure including a lower insulating layer and an upper insulating layer, and the etching of the second insulating layer may be performed by etching the upper insulating layer.

The source electrode and the drain electrode may include aluminum.

The source electrode and the drain electrode may have a triple-layered structure including a lower layer including molybdenum, a middle layer including aluminum, and an upper layer including molybdenum.

The manufacturing method may further include annealing the substrate after etching the second insulating layer.

The manufacturing method may further include forming a passivation layer on the source electrode and the drain electrode, and forming a pixel electrode on the passivation layer.

The forming of the second insulating layer may include depositing an insulating layer on the gate electrode, annealing the substrate including the insulating layer, and patterning the insulating layer by photolithography to form a plurality of contact holes exposing the semiconductor.

### BRIEF DESCRIPTION OF THE DRAWINGS

FIG. 1 is a block diagram of an LCD according to an embodiment of the present invention;

FIG. 2 is an equivalent circuit diagram of a pixel of an LCD according to an embodiment of the present invention;

FIG. 3 is a layout view of a display area of the TFT array panel shown in FIGS. 1 and 2 according to an embodiment of the present invention;

FIG. 4 is a sectional view of the display area shown in FIG. 3 taken along the lines IV-IV;

FIG. 5 is a layout view of a transistor in a driving area of TFT array panel shown in FIGS. 1 and 2 according to an embodiment of the present invention;

FIG. 6 is a sectional view of the thin film transistor shown in FIG. 5 taken along the lines VI-VI;

FIG. 7 and FIG. 8 are layout views of the TFT array panel shown in FIG. 3 to FIG. 6 in intermediate steps of a manufacturing method thereof according to an embodiment of the present invention;

FIG. 9 is a sectional view of the TFT array panel shown in FIG. 7 and FIG. 8 taken along the line IX-IX′-IX″;

FIG. 10 and FIG. 11 are layout views of the TFT array panel in the step following the step shown in FIG. 7 and FIG. 8;

FIG. 12 is a sectional view of the TFT array panel shown in FIG. 10 and FIG. 11 taken along the line XII-XII′-XII″;

FIG. 13 is a sectional view of the TFT array panel in the step following the step shown in FIG. 12;

FIG. 14 and FIG. 15 are layout views of the TFT array panel in the step following the step shown in FIG. 10 and FIG. 11;

FIG. 16 is a sectional view of the TFT array panel shown in FIG. 14 and FIG. 15 taken along the line XVI-XVI′-XVII″;

FIG. 17 and FIG. 18 are layout views of the TFT array panel in the step following the step shown in FIG. 14 and FIG. 15;

FIG. 19 is a sectional view of the TFT array panel shown in FIG. 17 and FIG. 18 taken along the line XIX-XIX′-XIX″;

FIG. 20A to FIG. 20E are sectional views of the TFT array panel shown in FIG. 17 to FIG. 19 in intermediate steps of a manufacturing method thereof;

FIG. 21 and FIG. 22 are layout views of the TFT array panel in the step following the step shown in FIG. 17 and FIG. 18; and

FIG. 23 is a sectional view of the TFT array panel shown in FIG. 21 and FIG. 22 taken along the line XIII-XIII′-XIII″.

### DETAILED DESCRIPTION OF THE EMBODIMENTS

It will be understood that when an element such as a layer, film, region, or substrate is referred to as being “on” another element, it can be directly on the other element or intervening elements may also be present. In contrast, when an element is referred to as being “directly on” another element, there are no intervening elements present.

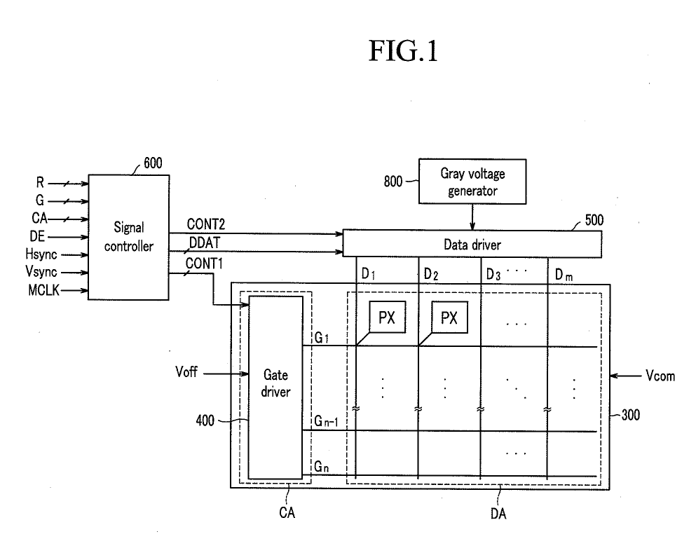

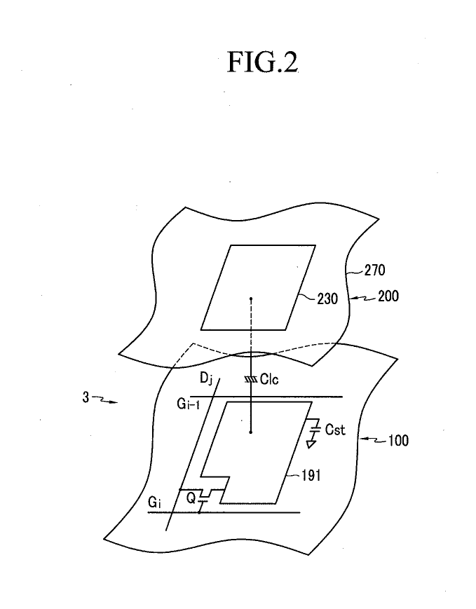

A liquid crystal display according to an embodiment of the present invention will be described with reference to FIG. 1 and FIG. 2.

FIG. 1 is a block diagram of an LCD according to an embodiment of the present invention and FIG. 2 is an equivalent circuit diagram of a pixel of an LCD according to an embodiment of the present invention.

Referring to FIG. 1, an display device according to the embodiment includes a display panel unit 300 including a gate driver 400, a data driver 500 that are connected to the display panel unit 300, a gray voltage generator 800 connected to the data driver 500, and a signal controller 600 controlling the above elements.

The display panel assembly 300 includes a display area DA directly related to image display and a control area CA related to the gate driver.

As shown in FIG. 1, the display area DA includes a plurality of gate lines G₁-Gₙ, a plurality of data lines D₁-Dₘ, a plurality of storage electrode lines (not shown), and a plurality of pixels PX connected thereto and arranged substantially in a matrix.

The control region CA includes the gate driver 400 generating gate signals and a plurality of signal transmitting lines (not shown) transmitting signals from the outside to the gate driver. The gate driver may be a shift register including a plurality of sequentially connected stages (not shown).

In the structural view shown in FIG. 2, the panel assembly 300 includes lower and upper panels 100 and 200 and an LC layer interposed therebetween. The display panel assembly 300 may include only one display panel if the example of display device is an organic light emitting device.

The gate lines G₁-Gₙ and the data lines D₁-Dₘ are disposed on the lower panel 100. The gate lines G₁-Gₙ transmit gate signals (also referred to as “scanning signals”) and the data lines D₁-Dₘ transmit data signals. The gate lines G₁-Gₙ extend substantially in a row direction and are substantially parallel to each other, while the data lines D₁-Dₘ extend substantially in a column direction and are substantially parallel to each other.

Each pixel PX includes at least one switching element Q (shown in FIG. 2) such as a thin film transistor, and at least one LC capacitor C_{LC} (shown in FIG. 2).

Referring to FIG. 2, each pixel PX defined by the ‘i’^{th} gate line and the ‘j’^{th} data line of a liquid crystal display includes a switching element Q connected to the signal lines Gᵢ and Dⱼ, and an LC (“liquid crystal”) capacitor C_{LC} and a storage capacitor C_{ST} that are connected to the switching element Q. The display signal lines Gᵢ and Dⱼ are provided on a lower panel 100. In some embodiments, the storage capacitor C_{ST} may be omitted.

The switching element Q such as a TFT including polysilicon is provided on a lower panel 100, and has three terminals: a control terminal connected to one of the gate lines G₁-Gₙ; an input terminal connected to one of the data lines D₁-Dₘ; and an output terminal connected to both the LC capacitor Clc and the storage capacitor Cst.

The LC capacitor Clc includes a pixel electrode 191 provided on the lower panel 100 and a common electrode 270 provided on an upper panel 200, as two terminals. The LC layer 3 disposed between the two electrodes 191 and 270 functions as a dielectric of the LC capacitor Clc. The pixel electrode 191 is connected to the switching element Q, and the common electrode 270 is supplied with a common voltage Vcom and covers an entire surface of the upper panel 200. Unlike in FIG. 2, the common electrode 270 may be provided on the lower panel 100, and both electrodes 190 and 270 may have shapes of bars or stripes.

The storage capacitor Cst is an auxiliary capacitor for the LC capacitor Clc. The storage capacitor Cst includes the pixel electrode 191, and a separate signal line that is provided on the lower panel 100, that overlaps the pixel electrode 191 via an insulator, and that is supplied with a predetermined voltage such as the common voltage Vcom. Alternatively, the storage capacitor Cst includes the pixel electrode 191 and an adjacent gate line called a previous gate line, which overlaps the pixel electrode 191 via an insulator.

For color display, each pixel PX uniquely represents one of three primary colors (i.e., spatial division), or each pixel PX represents three primary colors in turn (i.e., time division), such that a spatial or temporal sum of the three primary colors is recognized as a desired color. The three primary colors may include red, green, and blue. FIG. 2 shows an example of the spatial division in which each pixel is provided with a color filter 230, i.e., one of red, green, and blue color filters, in an area of the upper panel 200 facing the pixel electrode 191. Alternatively, the color filter 230 is provided on or under the pixel electrode 190 on the lower panel 100.

One or more polarizers (not shown) are attached to at least one of the panels 100 and 200.

Though not shown, each pixel PX of an organic light emitting display may include a switching element (not shown) connected to the signal lines G₁-Gₙ and D₁-Dₘ, a driving element (not shown), storage capacitors that are connected to the switching and the driving elements, and an organic light emitting diode (OLED, not shown). The OLED may include an anode (hole injection electrode), a cathode (electron injection electrode), and an organic light emission member interposed therebetween.

Referring to FIG. 1 again, the gray voltage generator 800 generates a plurality of gray voltages related to the transmittance of the pixels PX. The gray voltage generator 800 for the liquid crystal display generates two sets of a plurality of gray voltages. Here, the gray voltages in one set have a positive polarity with respect to the common voltage Vcom, while those in the other set have a negative polarity with respect to the common voltage Vcom.

The gate driver 400 is connected to the gate lines G₁-Gₙ of the display area DA and synthesizes the gate-on voltage Von and the gate-off voltage Voff from an external device to generate gate signals for application to the gate lines G₁-Gₙ. The gate driver 400 is mounted on the panel assembly 300 as IC chips, and it may include a plurality of driving circuits (not shown). Each driving circuit of the gate driver 400 is respectively connected to one gate line G₁-Gₙ, and includes a plurality of polysilicon thin film transistors with N- and P-types, or a complementary type. However, the gate driver 400 may be mounted on flexible printed circuit (FPC) films as a TCP (tape carrier package), and are attached to the display panel unit 300.

The data driver 500 is connected to the data lines D₁-Dₘ of the display panel unit 300 and applies data voltages, which are selected from the gray voltages supplied from the gray voltage generator 800, to the data lines D₁-Dₘ. The data driver 500 may be mounted on flexible printed circuit (FPC) films as a TCP (tape carrier package), and are attached to the display panel unit 300. Alternatively, the data driver 500 may be integrated into the display panel unit 300 as IC chips.

The IC chips of the drivers 400 and 500, or the flexible printed circuit (FPC) films are located at a peripheral area outside of the display area DA of the display panel unit 300.

The signal controller 600 controls the gate driver 400 and the data driver 500, and may be mounted on a printed circuit board (PCB).

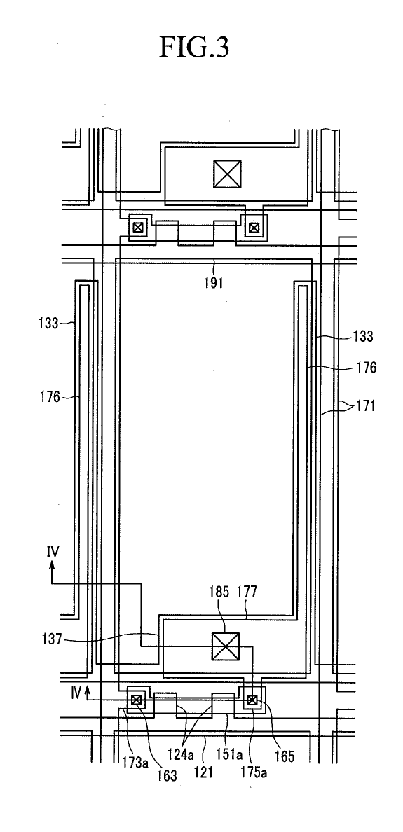

A TFT array panel for an LCD according to an embodiment of the present invention will now be described in detail with reference to FIGS. 3 to 6 as well as FIGS. 1 and 2.

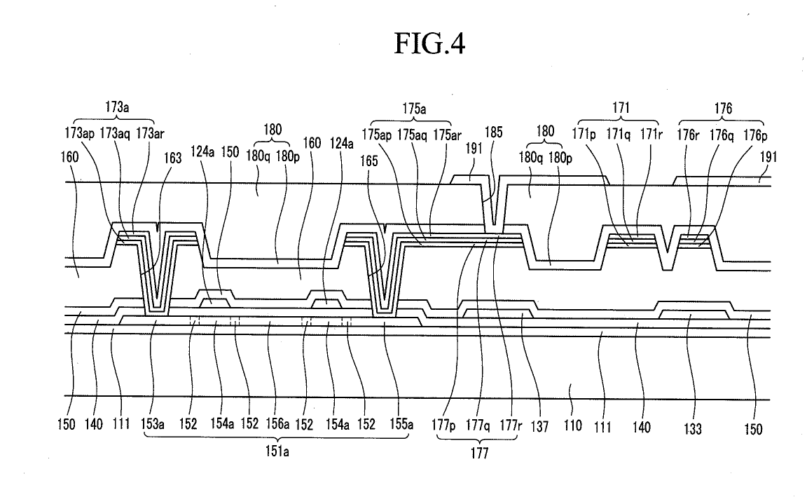

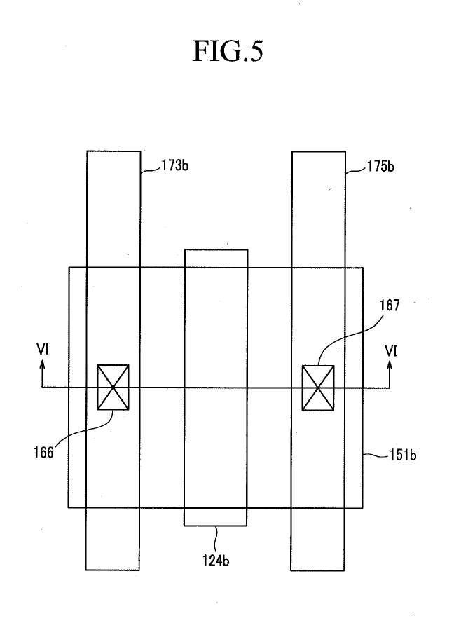

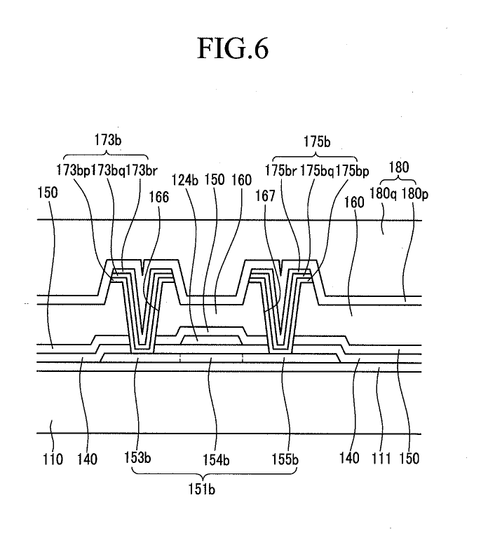

FIG. 3 is a layout view of a display area of the TFT array panel shown in FIGS. 1 and 2 according to an embodiment of the present invention, FIG. 4 is a sectional view of the display area shown in FIG. 3 taken along the lines IV-IV, FIG. 5 is a layout view of a transistor in a driving area of TFT array panel shown in FIGS. 1 and 2 according to an embodiment of the present invention, and FIG. 6 is a sectional view of the thin film transistor shown in FIG. 5 taken along the lines VI-VI.

N-type and P-type will be respectively described with regard to pixels PX and the gate driver 400 as examples of thin film transistors according to embodiments of the present invention.

A blocking film 111, preferably made of silicon oxide (SiO₂) or silicon nitride (SiNx), is formed on an insulating substrate 110 such as transparent glass, quartz, or sapphire. The blocking film 111 may have a dual-layered structure.

A plurality of semiconductor islands 151a for the display area DA and a plurality of semiconductor islands 151b for the control area CA, preferably made of polysilicon, are formed on the blocking film 111.

Each of the semiconductor islands 151a and 151b includes a plurality of extrinsic regions containing N-type or P-type conductive impurities, and at least one intrinsic region containing little of the conductive impurities. The extrinsic region includes a heavily doped region and a lightly doped region.

With regard to the semiconductor island 151a for the display area, the intrinsic regions include a channel region 154a, and the extrinsic regions include a plurality of heavily doped regions such as source and drain regions 153a and 155a separated from each other with respect to the channel region 154a, and a middle region 156a. The extrinsic regions further include a plurality of lightly doped regions 152 disposed between the intrinsic regions 154a and the heavily doped regions 153a, 155a, and 156a and having relatively small widths. The lightly doped regions 152 disposed between the source region 153a and the channel region 154a and between the drain region 155a and the channel region 154a are referred to as “lightly doped drain (LDD) regions”. The LDD regions prevent leakage current or punch-through from the TFTs. In other embodiments, the LDD regions may be replaced with offset regions that contain substantially no impurities, and may be omitted.

With regard to the semiconductor island 151b for the driver region, the intrinsic regions include a channel region 154b, and the extrinsic regions include a plurality of heavily doped regions such as source and drain regions 153b and 155b separated from each other with respect to the channel region 154b.

Boron (B) or gallium (Ga) may be used as the P-type impurity, and phosphorus (P) or arsenic (As) can be used as the N-type impurity.

A gate insulating layer 140 made of silicon oxide (SiO₂) or silicon nitride (SiNx) is formed on the semiconductor islands 151a and 151b, and on the blocking film 111.

A plurality of gate conductors including a plurality of gate lines 121 having a plurality of gate electrodes 124a of the display area DA and a plurality of control electrodes 124b of the control area CA, and a plurality of storage electrode lines 131 are formed on the gate insulating layer 140, respectively.

The gate lines 121 for transmitting gate signals extend substantially in a transverse direction and include a plurality of gate electrodes 124a for pixels protruding downward to overlap the channel areas 154a of the semiconductor islands 151a. Each gate line 121 may include an expanded end portion having a large area for contact with another layer or an external driving circuit. The gate lines 121 may be directly connected to a gate driving circuit for generating the gate signals, which may be integrated into the substrate 110.

The control electrode 124b of the control region CA overlaps the channel region 154b of the semiconductor island 154b, and is connected to the signal line (not shown) to apply a control signal.

The storage electrode lines 131 are supplied with a predetermined voltage such as a common voltage. The storage electrode lines 131 include a plurality of expansions 137 protruding upward and a plurality of longitudinal parts 133 extending upward.

The gate conductors 121, 124a, and 124b, and the storage electrode lines 131 preferably include a low resistivity material including an Al-containing metal such as Al or an Al alloy (e.g. Al—Nd), a Ag-containing metal such as Ag or a Ag alloy, a Cu-containing metal such as Cu or a Cu alloy, a Mo-containing metal such as Mo or a Mo alloy, Cr, Ti, or Ta. The gate conductors 121, 124a, and 124b, and the storage electrode lines 131 may have a multi-layered structure including two films having different physical characteristics. One of the two films preferably includes a low resistivity metal comprising an Al-containing metal, an Ag-containing metal, or a Cu-containing metal for reducing signal delay or voltage drop in the gate conductors 121, 124a, and 124b, and the storage electrode lines 131. The other film preferably includes a material such as Cr, Mo, a Mo alloy, Ta, or Ti, which have good physical, chemical, and electrical contact characteristics with other materials such as indium tin oxide (ITO) and indium zinc oxide (IZO). Examples of suitable multi-layered structures include a lower Cr film and an upper Al (or Al alloy) film, and a lower Al (or Al alloy) film and an upper Mo film. In addition, the gate conductors 121, 124a, and 124b, and the storage electrode lines 131 may include various metals and conductors.

The gate electrodes 124a may overlap the lightly doped region 152.

The lateral sides of the gate conductors 121, 124a, and 124b, and the storage electrode line 131 are inclined relative to a surface of the substrate 110, and the inclination angles thereof range from about 30 to about 80 degrees.

A lower interlayer insulating layer 150 is formed on the gate conductors 121 and 124b, the storage electrode lines 131, and the gate insulating layer 140, and an upper interlayer insulating layer 160 is formed thereon. The lower interlayer insulating layer 150 may be made of an insulator such as silicon oxide (SiOₓ), and the upper interlayer insulating layer 160 may be made of an inorganic insulator such as silicon nitride or silicon oxide, an organic insulator, or a low dielectric insulator. The organic insulator and the low dielectric insulator may have a dielectric constant less than about 4.0, and the low dielectric insulator may include an insulating material such as a-Si:C:O and a-Si:O:F formed by plasma enhanced chemical vapor deposition (PECVD). The upper interlayer insulating layer 160 may be made of an organic insulator having photosensitivity.

The upper interlayer insulating layer 160 has a position-dependent thickness.

The upper interlayer insulating layer 160, the lower interlayer insulating layer 150, and the gate insulating layer 140 have a plurality of contact holes 163, 165, 166, and 167 exposing the source regions 153a, 153b and the drain region 155a, 155b, respectively.

A plurality of data conductors, which include a plurality of data lines 171 including a plurality of source electrodes 173a, and a plurality of drain electrodes 175a for the display area DA, and a plurality of input electrodes 173b and a plurality of output electrodes 175b for the control region CA, are formed on the interlayer insulating layer 160.

The data lines 171 for transmitting data voltages extend substantially in the longitudinal direction and intersect the gate lines 121. Each data line 171 includes a plurality of source electrodes 173a for pixels connected to the source regions 153a through the contact holes 163. Each data line 171 may include an expanded end portion having a large area for contact with another layer or an external driving circuit. The data lines 171 may be directly connected to a data driving circuit for generating the gate signals, which may be integrated into the substrate 110.

The drain electrodes 175a are separated from the source electrodes 173a and connected to the drain regions 155a through the contact holes 165. The drain electrodes 175a include a plurality of expansions 177 and a plurality of longitudinal parts 176 respectively overlapping the expansions 137 and the longitudinal parts 133 of the storage electrode lines 131. The longitudinal parts 133 of the storage electrode lines 131 are located between the longitudinal parts 176 of the drain electrode 175a and the boundary of the data lines 171 facing the drain electrode 175a such that the longitudinal parts 133 of the storage electrode lines 131 block signal interference between the longitudinal parts 176 of the drain electrode 175a and the data lines 171.

The input electrode 173b and the output electrode 175b are separated from each other, and may be connected to other signal lines.

The data conductors 171, 173b, 175a, and 175b have a triple-layered structure including a lower layer 171p, 173bp, 175ap, and 175bp, a middle layer 171q, 173bq, 175aq, and 175bq, and an upper layer 171r, 173br, 175ar, and 175br. In the drawing, the lower layer, the middle layer, and the upper layer of the data conductors 171, 173a, 173b, 175a, and 175b are denoted by additional characters p, q, and r, respectively. The lower layer 171p, 173bp, 175ap, and 175bp may be made of a refractory metal such as Ti, Cr, Mo, Ta, or alloys thereof, the middle layer 171q, 173bq, 175aq, and 175bq may be made of a low resistivity metal including an Al-containing metal such as Al and an Al alloy, and the upper layer 171r, 173br, 175ar, and 175br may be made of a refractory metal such as Ti, Cr, Mo, Ta, or alloys thereof.

Like the gate conductors 121, 124a, and 124b, the data conductors 171, 173b, 175a, and 175b have tapered lateral sides relative to a surface of the substrate 110, and the inclination angles thereof range from about 30 to about 80 degrees.

A portion of the upper interlayer insulating layer 160, which is not covered with the data conductors 171, 173b, 175a, and 175b, has a lower height than a portion of the upper interlayer insulating layer 160 covered with the data conductors 171, 173b, 175a, and 175b. The portion of the upper interlayer insulating layer 160, which is not covered with the data conductors 171, 173b, 175a, and 175b, may have a thickness of about 50% to about 70% of the portion of the upper interlayer insulating layer 160 covered with the data conductors 171, 173b, 175a, and 175b.

A passivation layer 180 is formed on the data conductors 171, 173b, 175a, and 175b and the upper interlayer insulating layer 160. The passivation layer 180 includes a lower passivation layer 180p and an upper passivation layer 180q. The lower passivation layer 180p may be made of an inorganic insulator such as silicon nitride or silicon oxide, and the upper passivation layer 180q may be made of an organic material having a good flatness characteristic. The upper passivation layer 180q may have photosensitivity and be made of a low dielectric insulating material such as a-Si:C:O and a-Si:O:F formed by PECVD. However, the passivation layer 180 may have a single-layered structure made of an inorganic insulator or an organic insulator.

The passivation layer 180 has a plurality of contact holes 185 exposing the expansions 177 of the drain electrodes 175a. The passivation layer 180 may have a plurality of contact holes (not shown) exposing the end portions of the data lines 171, and the passivation layer 180 and the interlayer insulating layer 160 may have a plurality of contact holes (not shown) exposing the end portions of the gate lines 121. The passivation layer 180 may be omitted in the control region CA.

A plurality of pixel electrodes 191 are formed on the passivation layer 180 in the display area DA. The pixel electrodes 191 are physically and electrically connected to the drain electrodes 175a through the contact holes 185 such that the pixel electrodes 191 is supplied with the data voltages from the drain regions 155a via the drain electrodes 175a. The pixel electrodes 191 are preferably made of at least one of a transparent conductor such as ITO or IZO and opaque reflective conductor such as Al, Ag, or Cr.

The pixel electrodes 191 supplied with the data voltages generate electric fields in cooperation with the common electrode 270 on the upper panel 200. These electric fields determine orientations of liquid crystal molecules in a liquid crystal layer 3 disposed between the upper panel 200 and the lower panel 100. The pixel electrodes 191 may also supply an electrical current to a light emitting member (not shown) to cause the light emitting member to emit light.

Referring to FIG. 2, a pixel electrode 191 and a common electrode 270 form a liquid crystal capacitor C_{LC}, which stores applied voltages after turn-off of the TFT Q. The pixel electrode 191 and the portion of the drain electrode 175a connected thereto, and the storage electrode line 131 including the storage electrodes 137, form a storage capacitor C_{ST}.

When the passivation layer 180 is made of an organic material having a low dielectric constant, the pixel electrodes 191 may overlap the gate lines 121 and the data lines 171 to increase the aperture ratio of the display.

Meanwhile, the gate conductors 121 and 124b and the storage electrode lines 131 may be disposed under the semiconductor islands 154a and 154b via the gate insulating layer 140.

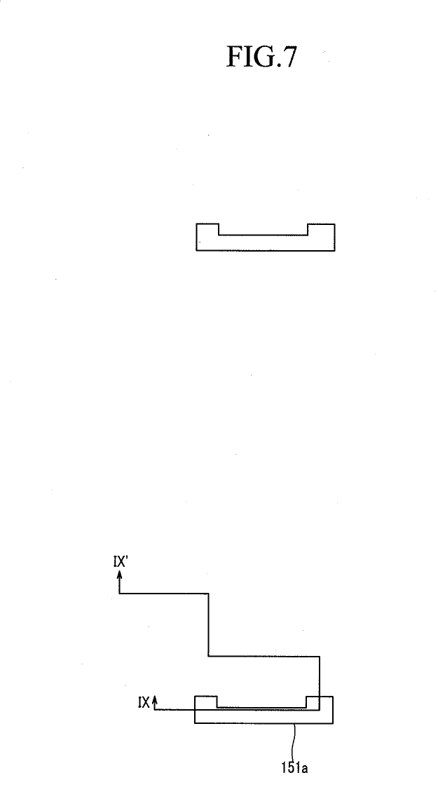

Now, a method of manufacturing the TFT array panel shown in FIG. 1 to FIG. 6 according to an embodiment of the present invention will now be described in detail with reference to FIG. 7 to FIG. 23 along with FIG. 1 to FIG. 6.

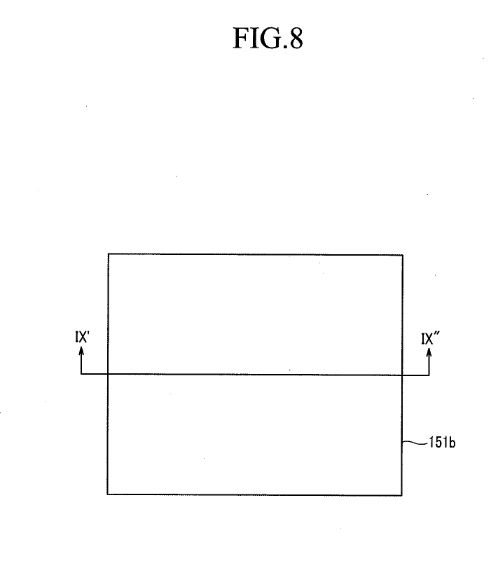

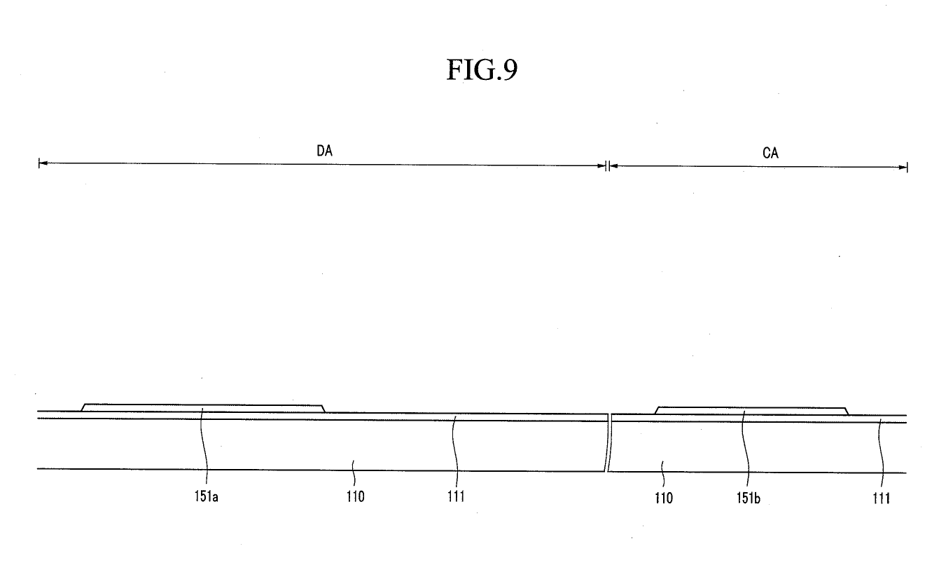

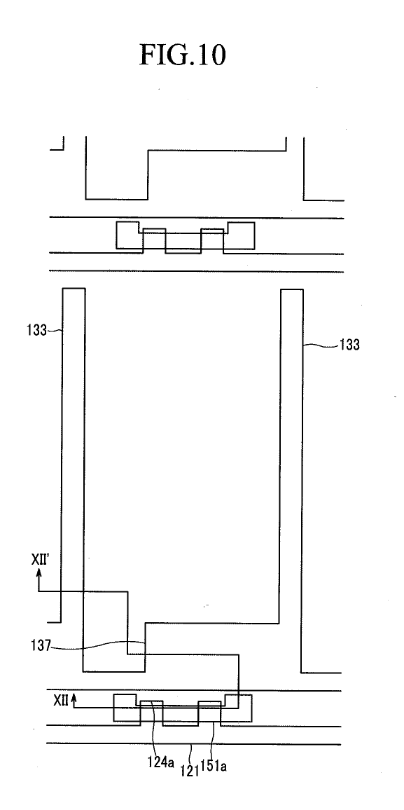

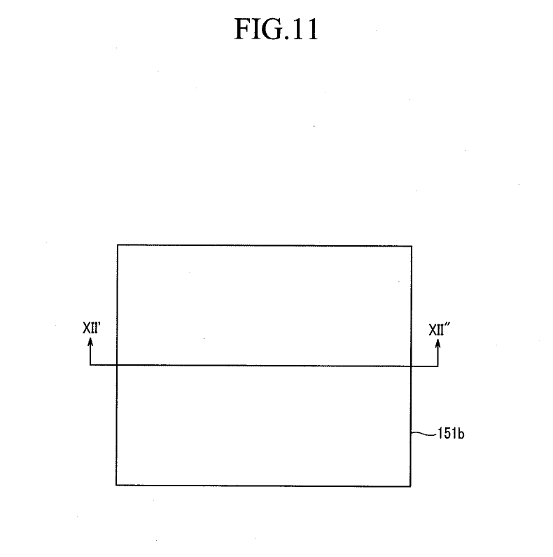

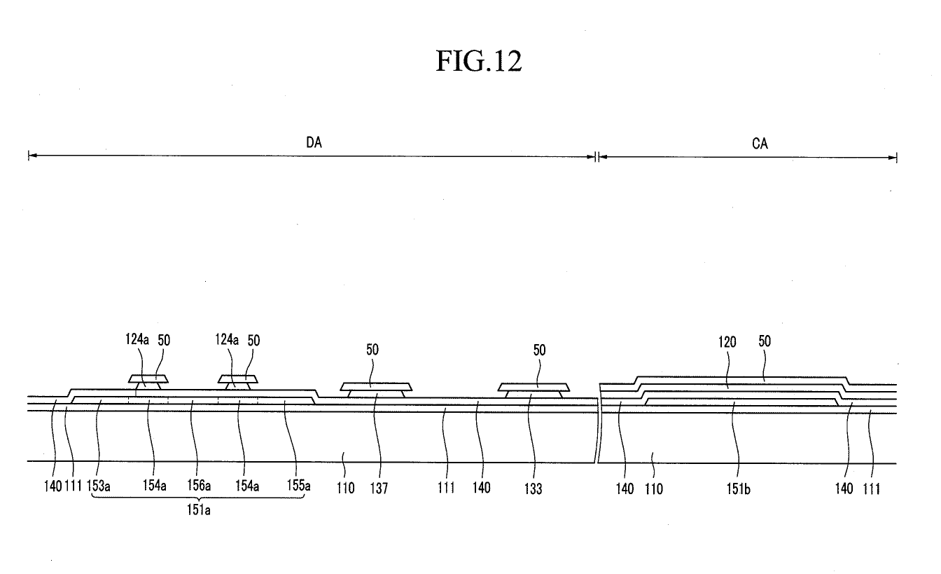

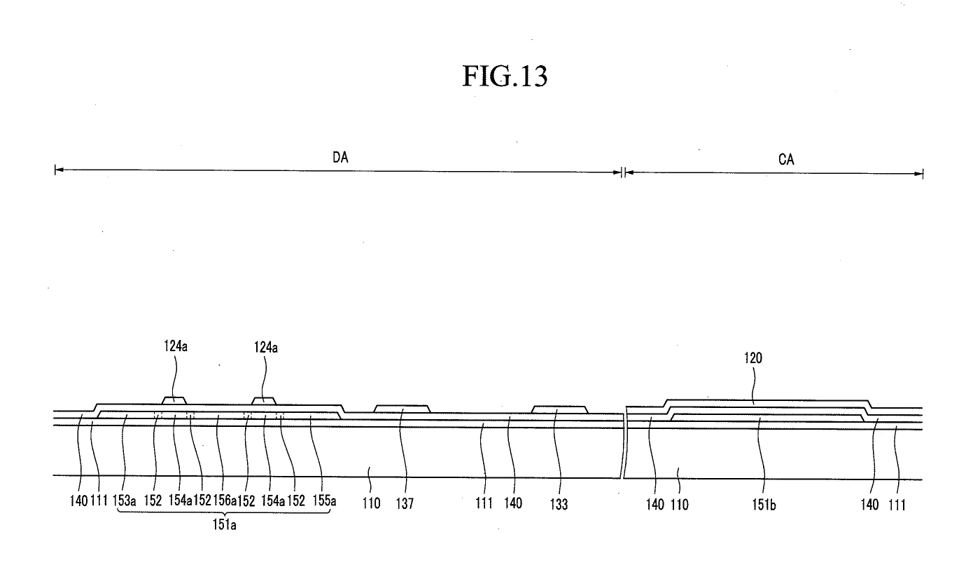

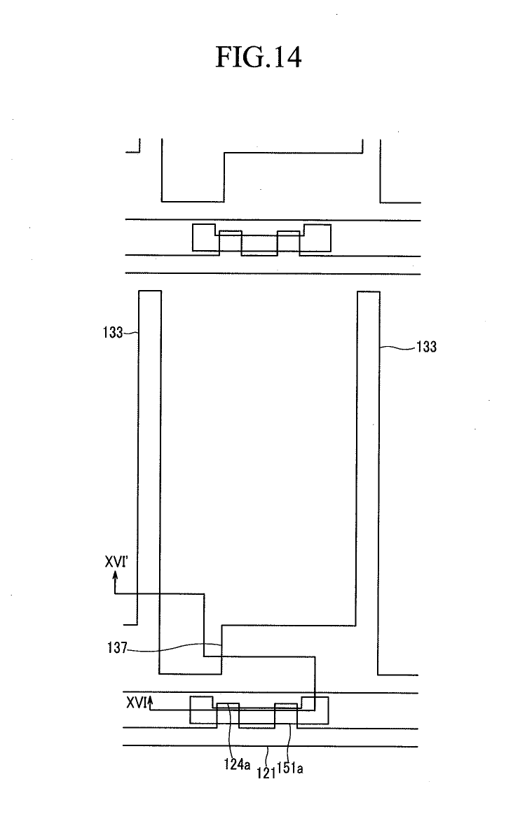

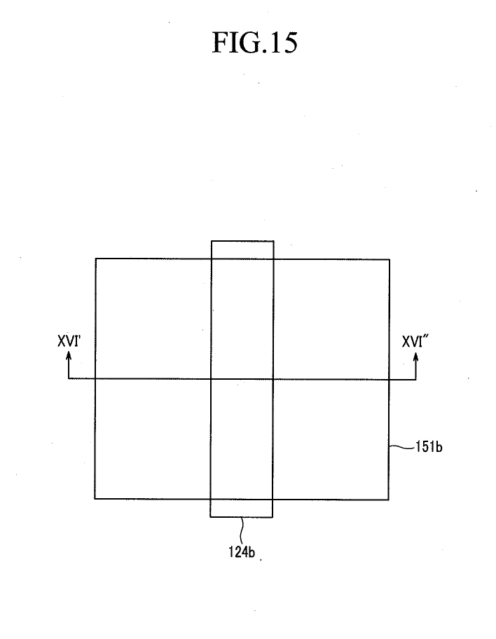

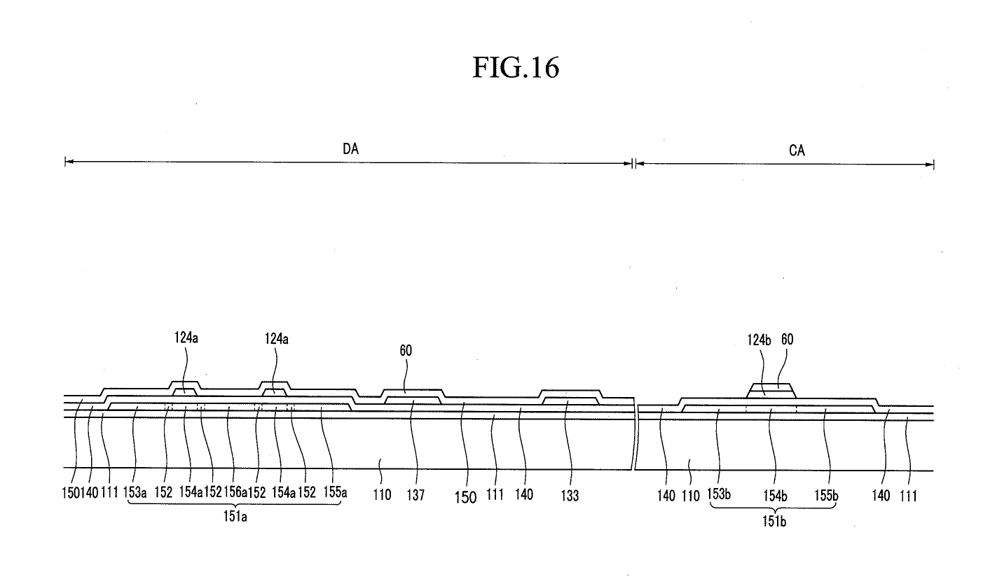

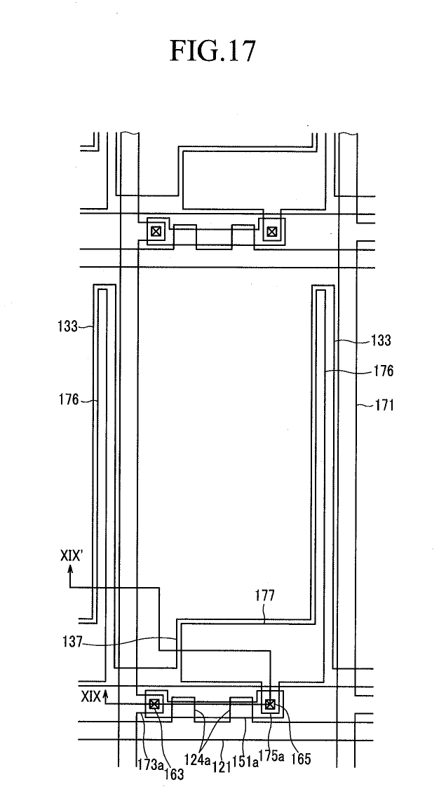

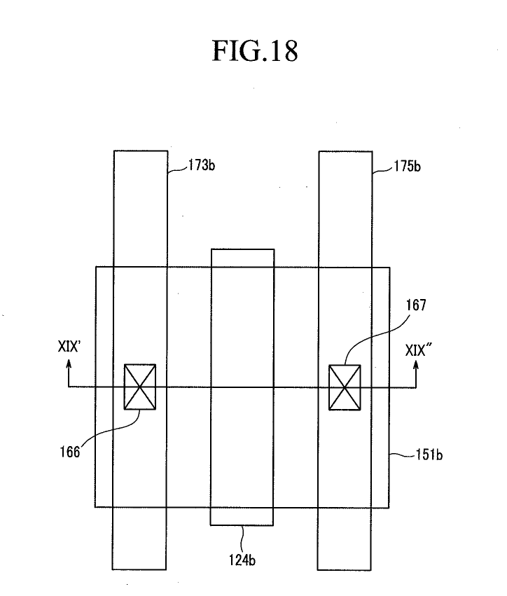

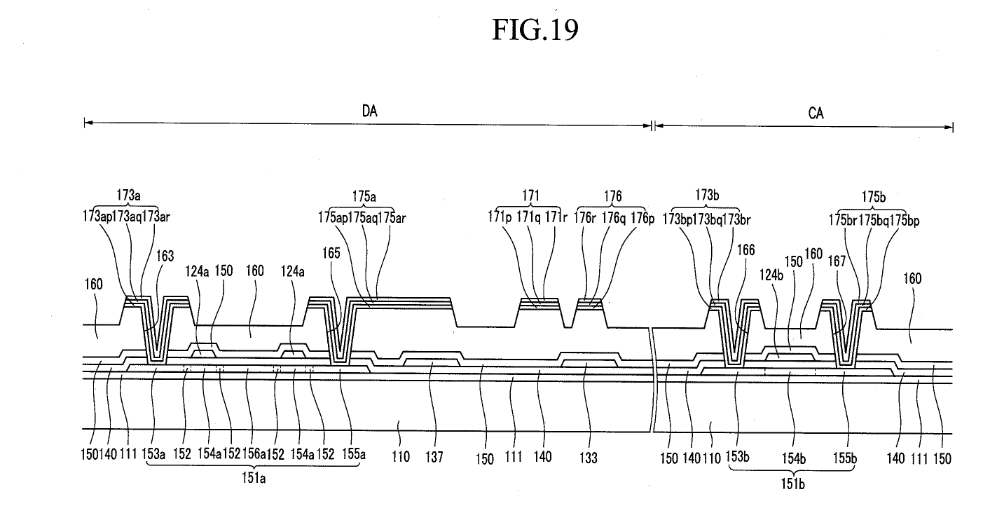

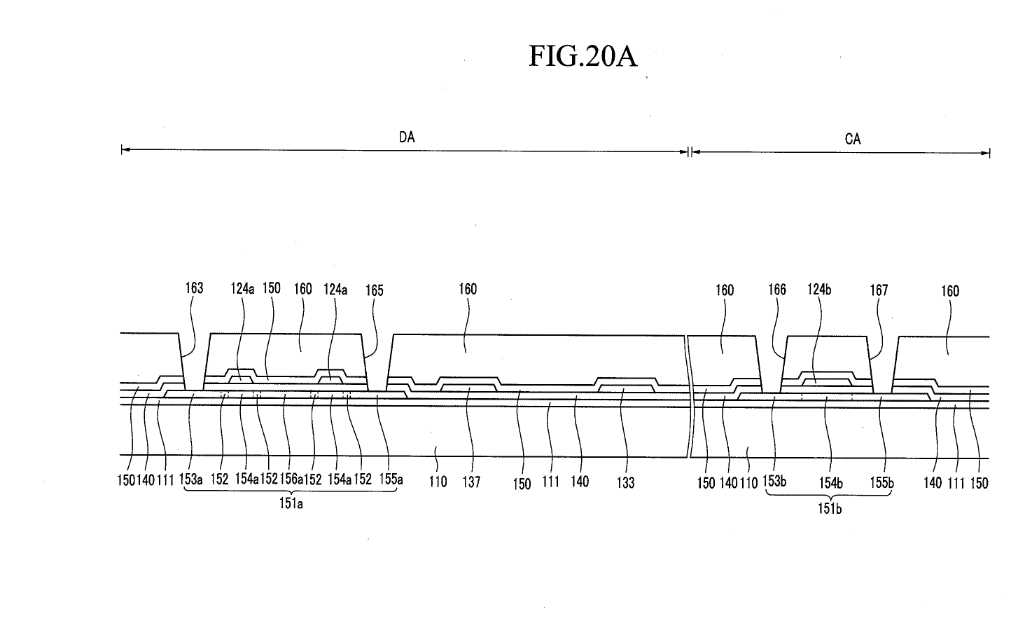

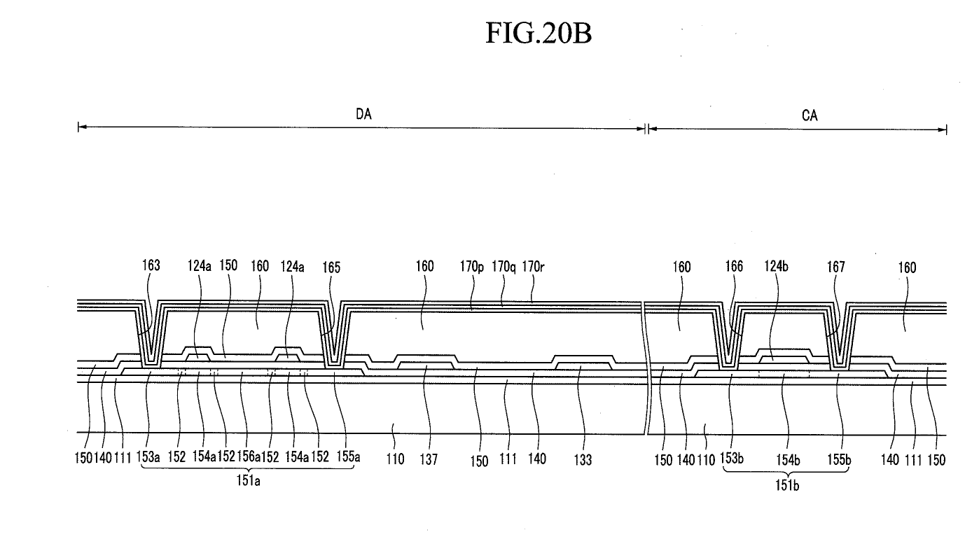

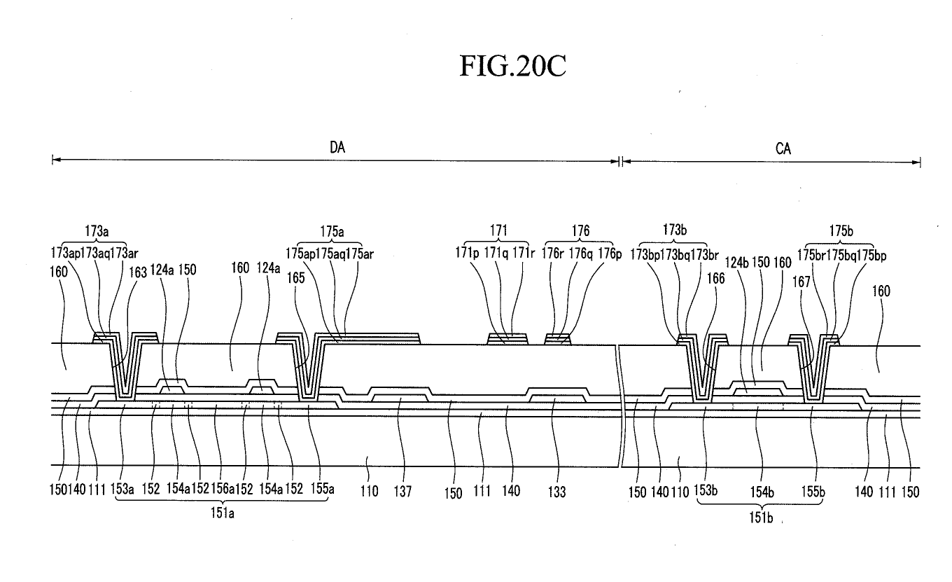

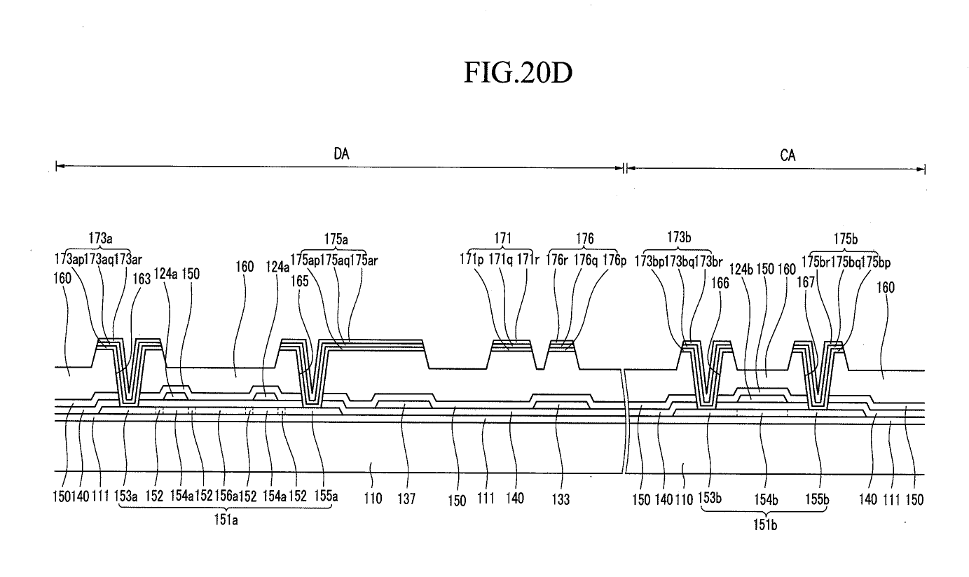

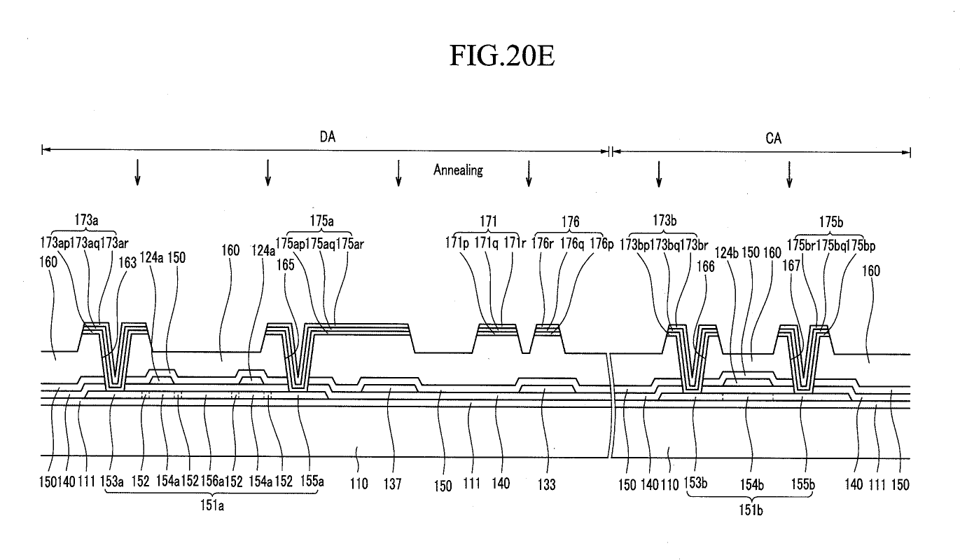

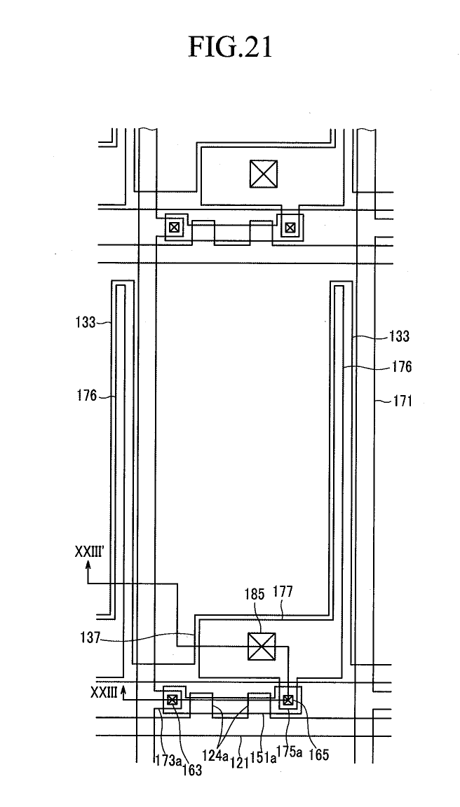

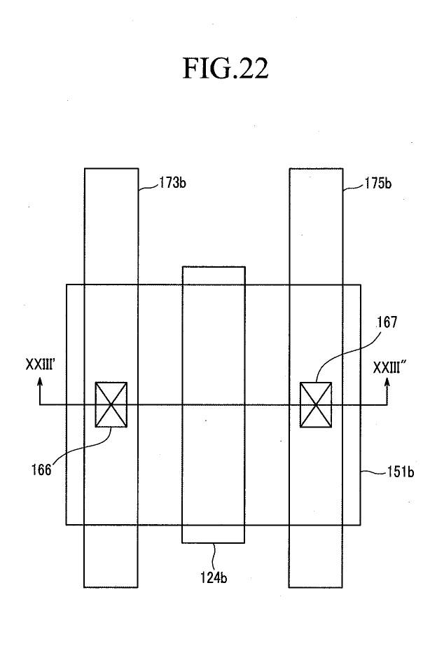

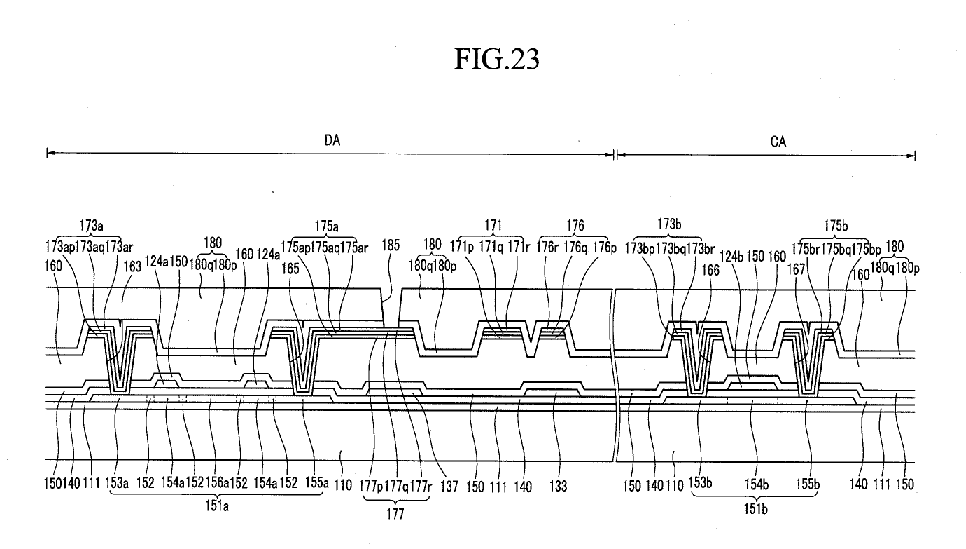

FIG. 7 and FIG. 8 are layout views of the TFT array panel shown in FIG. 3 to FIG. 6 in intermediate steps of a manufacturing method thereof according to an embodiment of the present invention, FIG. 9 is a sectional view of the TFT array panel shown in FIG. 7 and FIG. 8 taken along the line IX-IX′-IX″, FIG. 10 and FIG. 11 are layout views of the TFT array panel in the step following the step shown in FIG. 7 and FIG. 8, FIG. 12 is a sectional view of the TFT array panel shown in FIG. 10 and FIG. 11 taken along the line XII-XII′-XII″, FIG. 13 is a sectional view of the TFT array panel in the step following the step shown in FIG. 12, FIG. 14 and FIG. 15 are layout views of the TFT array panel in the step following the step shown in FIG. 10 and FIG. 11, FIG. 16 is a sectional view of the TFT array panel shown in FIG. 14 and FIG. 15 taken along the line XVI-XVI′-XVII″, FIG. 17 and FIG. 18 are layout views of the TFT array panel in the step following the step shown in FIG. 14 and FIG. 15, FIG. 19 is a sectional view of the TFT array panel shown in FIG. 17 and FIG. 18 taken along the line XIX-XIX′-XIX″, FIG. 20A to FIG. 20E are sectional views of the TFT array panel shown in FIG. 17 to FIG. 19 in intermediate steps of a manufacturing method thereof, FIG. 21 and FIG. 22 are layout views of the TFT array panel in the step following the step shown in FIG. 17 and FIG. 18, and FIG. 23 is a sectional view of the TFT array panel shown in FIG. 21 and FIG. 22 taken along the line XIII-XIII′-XIII″.

Referring to FIG. 7 to FIG. 9, a blocking film 11 is formed on an insulating substrate 110, and a semiconductor layer preferably made of amorphous silicon is deposited thereon by chemical vapor deposition (CVD) or sputtering. The semiconductor layer is then crystallized by laser annealing, furnace annealing, or solidification, and patterned by lithography and etching to form a plurality of semiconductor islands 151a for a display area DA and a plurality of semiconductor islands 151b for a control region CA.

Referring to FIG. 10 to FIG. 12, a gate insulating layer 140 preferably made of silicon oxide or silicon nitride is deposited on the semiconductor islands 151a and 151b and the substrate 110 by CVD, and a gate conductor film 120 is sequentially deposited on the gate insulating layer 140 thereon. Then a first photosensitive film 50 is formed on the gate conductor film 120. Here, the first photosensitive film 50 entirely covers the semiconductor islands 151b for the control region CA, and is disposed on a portion of the semiconductor islands 151a for the display area DA.

The gate conductor film 120 is etched using the first photosensitive film 50 as an etch mask to form a plurality of gate lines 121 including a plurality of gate electrodes 124a and a plurality of storage electrode lines 131 including a plurality of storage electrodes 137 for the display area DA. At this time, the gate conductor film is over-etched with respect to the doping mask. The over-etching makes edges of the gate lines 121, the gate electrodes 124a, the storage electrode lines 131, and the storage electrodes 137 lie within edges of the first photosensitive film 50.

Next, high-concentration N-type impurities are introduced into the semiconductor islands 151a by PECVD or plasma emulsion using the first photosensitive film 50 as an ion implant mask such that regions of the semiconductor islands 151a disposed under the first photosensitive film 50 are not doped and that remaining regions of the semiconductor islands 151a are heavily doped, thereby forming a plurality of high concentration extrinsic regions including a plurality of source and drain regions 153a and 155a and a plurality of dummy regions 156a, along with a plurality of channel regions 154a that are not doped.

Then, as shown in FIG. 13, the first photosensitive film 50 is removed and low-concentration N-type impurities are implanted using the gate electrodes 124a as an ion implant mask such that regions of the semiconductor islands 151a disposed under the gate electrodes 124a are not doped and remaining regions of the semiconductor islands 151a are heavily doped to form a plurality of lightly doped extrinsic regions 152 at both side portions of the channel regions 154a. Accordingly, the regions under the gate electrodes 124a between the source regions 153a and the drain regions 155a may not be doped to form channel regions 154a.

The lightly doped extrinsic regions 152 may be also made by forming spacers on side walls of the gate lines 121 and the storage electrode lines 131 in addition to the above described processes.

A second photosensitive film 60 is formed as shown in FIG. 14 to FIG. 16. Here, the second photosensitive film 60 entirely covers the display area DA, and is disposed on a portion of the control region CA. The gate conductor film 120 for the control region CA is etched using the second photosensitive film 60 as an etch mask to form a plurality of control electrodes 124b for the control region CA and then the second photosensitive film 60 is removed. Thereafter, high-concentration P-type impurities are implanted into the semiconductor islands 151b by PECVD or plasma emulsion using the control electrodes 124b as an ion implant mask such that regions of the semiconductor islands 151b disposed under the control electrodes 124b are not doped and remaining regions of the semiconductor islands 151b are heavily doped to form a plurality of source and drain regions 153b and 155b and a plurality of channel regions 154b.

As shown in FIG. 17 to FIG. 19, a lower interlayer insulating layer 150 made of silicon oxide and upper interlayer insulating layer 160 made of silicon nitride or silicon oxide are sequentially deposited and patterned along with the gate insulating layer 140 by photolithography along with the gate insulating layer 104 to form a plurality of contact holes 163, 165, 166, and 167 exposing the source regions 153a and 153b and the drain regions 155a and 155b. Heat-treatment, such as annealing is performed on the upper interlayer insulating layer 160 after deposition of the lower interlayer insulating layer 150 and the upper interlayer insulating layer 160 to improve characteristics of the implanted ions in the semiconductor islands 151a and 151b.

After formation of the lower interlayer insulating layer 150 and the upper interlayer insulating layer 160 having a plurality of contact holes 163, 165, 166, and 167, a plurality of data conductors are formed. The data conductors include a plurality of data lines 171, source electrodes 173a connected to the source regions 153a through the contact holes 163 and a plurality of drain electrodes 175a connected to drain regions 155a through the contact holes 165 for the display area DA. Also formed are a plurality of input electrodes 173b and output electrodes 175b connected to the source regions 153b and the drain regions 155b through the contact holes 166 and 167 for the control region CA.

The upper interlayer insulating layer 160 has a position-dependent thickness. Portions of the upper interlayer insulating layer 160 not covered with the data conductors 171, 173b, 175a, and 175b are partially eliminated.

Accordingly, portions of the upper interlayer insulating layer 160, that are not covered with the data conductors 171, 173b, 175a, and 175b, have a lower height than portions of the upper interlayer insulating layer 160 that are covered with the data conductors 171, 173b, 175a, and 175b. The portions of the upper interlayer insulating layer 160, which are not covered with the data conductors 171, 173b, 175a, and 175b, may have a thickness of about 50% to about 70% of the portion of the upper interlayer insulating layer 160 covered with the data conductors 171, 173b, 175a, and 175b.

A method of manufacturing the TFT array panel shown in FIG. 17 to FIG. 19 will be described in detail with reference to FIG. 20A to FIG. 20E along with FIG. 17 to FIG. 19.

Referring to FIG. 20A, the lower interlayer insulating layer 150 and the upper interlayer insulating layer 160 are sequentially deposited on the entire substrate 110 and patterned by photolithography along with the gate insulating layer 140 to form a plurality of contact holes 163, 165, 166, and 167 exposing the source regions and the drain regions 153a, 155a, 153b, and 153b, respectively. After deposition of the lower interlayer insulating layer 150 and the upper interlayer insulating layer 160 and before patterning by photolithography, annealing is performed to improve characteristics of the implanted ion in the semiconductor islands 151a and 151b.

Referring to FIG. 20B, a data conductor film 170, which includes a lower layer 170p made of Ti or an alloy thereof, a middle layer 170q made of Al or an alloy thereof, and an upper layer 170r made of Ti or an alloy thereof, is deposited by sputtering, etc. A photosensitive film (not shown) is coated on the data conductor film 170, and the photosensitive film is exposed and developed to form photoresist patterns (not shown). The data conductor film 170 is etched using the photoresist patterns as an etch mask to form a plurality of data conductors including a plurality of data lines 171 including a plurality of source electrodes 173a and a plurality of drain electrode 175a for the display area DA, and a plurality of input electrodes 173b and a plurality of output electrodes 175b for the control region CA.

Referring to FIG. 20D, the upper interlayer insulating layer 160 is etched using the photoresist patterns or the data conductors 171, 173b, 175a, and 175b as an etch mask such that portions of the upper interlayer insulating layer 160 not covered with the data conductors are partially eliminated to become thin. The eliminated upper interlayer insulating layer 160 is about 30% to about 50% of the original upper interlayer insulating layer 160 in thickness. Accordingly, the remaining upper interlayer insulating layer 160, which is not covered with the data conductors 171, 173b, 175a, and 175b, may have a thickness of about 50% to about 70% of the portion of the upper interlayer insulating layer 160 covered with the data conductors 171, 173b, 175a, and 175b.

Then, annealing is performed to improve characteristics of the implanted ions in the semiconductor islands 151a and 151b and to improve contact characteristics between the semiconductor 151a and the source and drain electrodes 173a and 175a, and between the semiconductor 151b and the input and output electrodes 173b and 175.

During the annealing, aluminum material contained in the middle layer 171q, 173bq, 175aq, 175bq of the data conductors 171, 173b, 175a, 175b may be diffused or migrate to develop a short circuit between the data conductors 171, 173b, 175a, and 175b. However, in the display device according to an embodiment of the present invention, the data conductors 171, 173b, 175a, and 175b are disposed on the higher upper interlayer insulating layer 160 than the others such that the diffused or migrating aluminum material is placed on the lower upper interlayer insulating layer 160 and is prevented from reaching the data conductors 171, 173b, 175a, and 175b. Accordingly, a short circuit between the data conductors 171, 173b, 175a, and 175b due to the diffused or migrating aluminum material is prevented.

Referring to FIG. 21 to FIG. 23, a lower passivation layer 180p made of an inorganic insulator is deposited by CVD, etc., and an upper passivation layer 180q made of a photosensitive organic insulator is substantially coated.

Thereafter, the upper passivation layer 180q is exposed through a photo mask (not shown) and developed to expose portions of the lower passivation layer 180p, and the exposed lower passivation layer 180p is etched by dry etching to form a plurality of contact holes 185 exposing the expansions 177 of the drain electrodes 175a of the display area DA.

Referring to FIG. 3 and FIG. 4, a transparent conductive material such as IZO (indium zinc oxide) and ITO (indium tin oxide) is deposited and patterned to form a plurality of pixel electrodes 191 for the display area DA connected to the drain electrodes 175a through the contact holes 185.

As described above, the upper interlayer insulating layer 160 is etched such that portions of the upper interlayer insulating layer 160 not covered with the data conductors are partially eliminated and thinned. Because the data conductors 171, 173b, 175a, and 175b are disposed on the higher upper interlayer insulating layer 160 than the others, diffused or migrating aluminum material placed on the lower upper interlayer insulating layer 160 is prevented from being connected to the data conductors 171, 173b, 175a, and 175b. Accordingly, a short circuit is prevented among the data conductors 171, 173b, 175a, and 175b due to the diffused or migrating aluminum material during the annealing.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display panel, comprising:
a semiconductor layer formed on a substrate;
a first insulating layer formed on the semiconductor layer;
a gate line including a gate electrode and formed on the first insulating layer;
a second insulating layer formed on the gate line; and
a data line including a source electrode and a drain electrode formed on the second insulating layer,
wherein the second insulating layer covered with the drain electrode and the data line is thicker than the second insulating layer not covered with the drain electrode and the data line.

2. The display panel of claim 1, wherein the thickness of the second insulating layer not covered with the drain electrode and the data line is about 50% to 70% of that of the second insulating layer covered with the drain electrode and the data line.

3. The display panel of claim 2, wherein the second insulating layer has a dual-layered structure including a lower insulating layer and an upper insulating layer, wherein the lower insulating layer has a constant thickness and the upper insulating layer has a position-dependent thickness.

4. The display panel of claim 1, wherein the drain electrode and the data line comprise aluminum.

5. The display panel of claim 1, wherein the drain electrode and the data line have a triple-layered structure including a lower layer comprising molybdenum, a middle layer comprising aluminum, and an upper layer comprising molybdenum.

6. The display panel of claim 1, wherein the first insulating layer and the second insulating layer have first and second contact holes exposing the semiconductor layer, and the source electrode and the drain electrode are connected to the semiconductor layer through the first contact hole and the second contact hole, respectively.

7. The display panel of claim 6, further comprising:
a passivation layer formed on the data line; and
a pixel electrode formed on the passivation layer.

8. A manufacturing method of a display panel, comprising:
forming a semiconductor layer on a substrate;
forming a first insulating layer on the semiconductor layer;
forming a gate electrode on the first insulating layer;
forming a second insulating layer on the gate electrode;
forming a source electrode and a drain electrode on the second insulating layer; and
etching the second insulating layer using the source electrode and the drain electrode as an etch mask to become thin.

9. The manufacturing method of claim 8, wherein the thickness of the second insulating layer not covered with the source electrode and the drain electrode is about 50% to 70% of that of the second insulating layer covered with the source electrode and the drain electrode.

10. The manufacturing method of claim 9, wherein the second insulating layer has a dual-layered structure including a lower insulating layer and an upper insulating layer, and the etching of the second insulating layer is performed by etching the upper insulating layer.

11. The manufacturing method of claim 10, wherein the source electrode and the drain electrode comprise aluminum.

12. The manufacturing method of claim 11, wherein the source electrode and the drain electrode have a triple-layered structure including a lower layer comprising molybdenum, a middle layer comprising aluminum, and an upper layer comprising molybdenum.

13. The manufacturing method of claim 12, further comprising annealing the substrate after etching the second insulating layer.

14. The manufacturing method of claim 13, further comprising
forming a passivation layer on the source electrode and the drain electrode; and
forming a pixel electrode on the passivation layer.

15. The manufacturing method of claim 14, wherein the forming of the second insulating layer comprises:
depositing an insulating layer on the gate electrode;
annealing the substrate including the insulating layer; and
patterning the insulating layer by photolithography to form a plurality of contact holes exposing the semiconductor.
